(19) United States
(12) Patent Application Publication
(10) Pub. No.: US 2025/0372413 A1
(43) Pub. Date: Dec. 4, 2025

(54) SYSTEMS AND METHODS THAT UTILIZE METAL-COATED PROCESSING HEADS TO IMPROVE WET PROCESSING OF SEMICONDUCTOR SUBSTRATES

(71) Applicant: Tokyo Electron Limited, Tokyo (JP)

(72) Inventor: Shan Hu, Albany, NY (US)

(21) Appl. No.: 18/733,473

(22) Filed: Jun. 4, 2024

(51) Int. Cl. H01L 21/67; H01L 21/306; H01L 21/68

(52) U.S. Cl. CPC H01L 21/6708; H01L 21/30608; H01L 21/68

(57) ABSTRACT

Various embodiments of wet processing systems and methods that utilize metal assisted chemical etching (MacEtch) to process a semiconductor substrate are provided herein. The disclosed embodiments utilize a processing head having one or more metal surfaces (otherwise referred to herein as a metal-coated processing head) to catalyze the MacEtch reactions that occur at the interface between the metal surface(s) of the processing head and the surface of a semiconductor substrate when the substrate surface is exposed to an etch solution. The metal-coated processing head can be used to perform a wide variety of MacEtch processes on the substrate surface and/or within the semiconductor substrate. For example, the metal-coated processing head can be used to etch features (such as, e.g., holes, trenches, circular disks, etc.) within the semiconductor substrate, or remove high points on substrate surface to smooth the substrate surface.

### BACKGROUND

The present disclosure relates to the processing of substrates. In particular, it provides systems and methods that use metal-coated processing heads to improve the wet processing of semiconductor substrates.

Semiconductor device formation typically involves a series of manufacturing techniques related to the formation, patterning, and removal of layers of material on a substrate. During routine semiconductor fabrication, various materials formed on a substrate may be removed by patterned etching, chemical-mechanical polishing (CMP), as well as other techniques. A variety of techniques are known for etching layers on a substrate, including plasma-based or vapor-phase etching (otherwise referred to as dry etching) and liquid based etching (otherwise referred to as wet etching).

Wet etching generally involves dispensing a chemical solution over the surface of a substrate or immersing the substrate in the chemical solution. The chemical solution (otherwise referred to herein as an etch solution) often contains a solvent and etchant chemical(s) designed to react with materials on the substrate surface and promote dissolution of the reaction products. As a result of exposure of the substrate surface to the etch solution, material is removed from the substrate. The composition and temperature of the etch solution may be controlled to control the etch rate, specificity, and residual material on the surface of the substrate post-etch.

Recently, metal assisted chemical etching (abbreviated as MacEtch or MaCE) has been investigated as an anisotropic wet etch technique for producing arrays of micro- and nanostructures (including, for example, holes, pillars, sheets, etc.) in a variety of semiconductor substrates, including silicon (Si), silicon carbide (SiC), silicon germanium (SiGe) and III-V compound semiconductor materials, such as gallium arsenide (GaAs) and gallium nitride (GaN). MacEtch deposits a noble metal catalyst (such as gold (Au), platinum (Pt), palladium (Pd), silver (Ag), etc.) onto a substrate surface exposed to an etch solution containing an oxidant and an acid (or base) to induce local reduction and oxidation reactions on the substrate surface. The noble metal catalyst deposited onto the substrate surface serves as a local cathode to catalyze the reduction of the oxidant, producing electron holes (h+) that are injected into the valence band of the substrate. The presence of the electron holes changes the oxidation state of the Si underlying the noble metal catalyst and enables the oxidation and selective removal of Si in the acidic etch solution. As the Si is removed beneath the catalyst, it sinks and contacts unreacted material, continuing the reaction to form a negative image of the catalytic mask. This results in the removal of semiconductor materials without net consumption of the noble metal.

FIGS. 1A-1C illustrate a conventional MacEtch process 100 used to etch a pattern of features 120 within a semiconductor substrate 110. The MacEtch process 100 begins in FIG. 1A by forming a noble metal pattern 105 (e.g., Au) on the surface of the semiconductor substrate 110 (e.g., Si). In FIG. 1B, the surface of the semiconductor substrate 110 is exposed to an etch solution 115 containing an oxidant (e.g., hydrogen peroxide, H₂O₂) and an acid (e.g., hydrofluoric acid, HF). The noble metal deposited onto the substrate surface catalyzes the reduction of the oxidant to locally increase the oxidation rate of the substrate surface, thereby increasing the local dissolution rate and etch rate of the substrate material underlying the noble metal pattern 105. Since MacEtch reactions occur only at the interface between the noble metal and the semiconductor substrate 110, the noble metal pattern descends into the semiconductor substrate 110 as the substrate is being etched to form the pattern of features 120 (e.g., holes, trenches, etc.), as shown in FIGS. 1B and 1C. Noble metal remaining at the bottom of the features 120 is removed in a subsequent process.

In the conventional MacEtch process 100 shown in FIGS. 1A-1C, the depth of the etched features is controlled by etching time. However, it is difficult to obtain deep, straight patterns of features 120 using the conventional MacEtch process 100 due to variations in the etching direction for prolonged etch processes. As shown in FIG. 1C, prolonged etching in the MacEtch process 100 tends to form bent holes. This prevents the MacEtch process 100 from being used within deep etch processes, such as those used to form through silicon vias (TSV).

### SUMMARY

The present disclosure provides various embodiments of wet processing systems and methods that utilize metal assisted chemical etching (MacEtch) to process a semiconductor substrate. Unlike conventional MacEtch processes, the systems and methods disclosed herein utilize a processing head having one or more metal surfaces (otherwise referred to herein as a metal-coated processing head) to catalyze the MacEtch reactions that occur at the interface between the metal surface(s) of the processing head and the surface of a semiconductor substrate when the substrate surface is exposed to an etch solution.

The metal-coated processing head can be used to perform a wide variety of MacEtch processes on the substrate surface and/or within the semiconductor substrate. For example, the metal-coated processing head can be used to catalyze MacEtch reactions when: (a) etching one or more features (e.g., one or more holes, trenches, circular disks, etc.) within the semiconductor substrate, or (b) removing high point(s) on substrate surface to smooth the substrate surface. The embodiments disclosed herein eliminate variations in etching direction by controlling movement of the metal-coated processing head and/or the semiconductor substrate, as the feature(s) are being etched or the substrate surface is being smoothed. In doing so, the disclosed embodiments provide significantly greater control over the etching process compared to conventional MacEtch processes, which rely on noble metal patterns deposited onto the substrate surface. The greater etching control enables the embodiments disclosed herein to form deep, straight holes and trenches within the semiconductor substrate, as well as unique structures (such as, e.g., angled holes and trenches, and horizontal holes, trenches or circular disks etched within vertically oriented trenches), which cannot be formed using conventional MacEtch processes.

According to one embodiment, a method is provided herein to process a semiconductor substrate. In general, the method may begin by receiving the semiconductor substrate within a wet processing system, the wet processing system comprising a processing head having one or more metal surfaces at a distal end of the processing head.

The method may further include: (a) exposing a substrate surface of the semiconductor substrate to an etch solution comprising an oxidant and an etchant while the semiconductor substrate is disposed within the wet processing system; (b) moving at least one of the processing head and the semiconductor substrate to position the one or more metal surfaces of the processing head in close proximity to the substrate surface while the substrate surface is exposed to the etch solution; and (c) performing a metal assisted chemical etching (MacEtch) process on the substrate surface and/or within the semiconductor substrate while the one or more metal surfaces of the processing head is positioned in close proximity to the substrate surface and the substrate surface is exposed to the etch solution. During the MacEtch process, the one or more metal surfaces of the processing head may catalyze a reduction of the oxidant and generate free holes, which are injected into portions of the substrate surface directly underlying the one or more metal surfaces to form ionic species that are dissolved by the etchant. Upon completion of the MacEtch process, at least one of the processing head and the semiconductor substrate may be moved to remove the one or more metal surfaces of the processing head from the substrate surface.

The metal surface(s) provided on the processing head catalyze the MacEtch reactions (e.g., the reduction and oxidation reactions) that occur at the interface between the noble metal surface(s) of the processing head and the surface of a semiconductor substrate when the substrate surface is exposed to the etch solution. In some embodiments, the one or more metal surfaces of the processing head may comprise a noble metal, such as gold (Au), silver (Ag), platinum (Pt), palladium (Pd), ruthenium (Ru), rhodium (Rh), osmium (Os) or iridium (Ir). In other embodiments, other metals such as iron (Fe), nickel (Ni), copper (Cu) and aluminum (Al) can also act as a catalyst in the MacEtch process.

The etch solution provided to the substrate surface may generally depend on the semiconductor material being etched. Etch solutions containing an oxidant and an etchant (e.g., an acid, base or water) are commonly used to etch silicon-containing materials. Examples of oxidants that may be used to etch silicon-containing materials include, but are not limited to, hydrogen peroxide (H₂O₂), nitric acid (HNO₃), potassium persulfate (K₂S₂O₈), oxygen (O₂) dissolved in water (H₂O) and ozonated water. Examples of etchants include, but are not limited to, hydrofluoric acid (HF), sulfuric acid (H₂SO₄), potassium hydroxide (KOH) and deionized water (H₂O). In one example embodiment, an etch solution containing a mixture of hydrogen peroxide (H₂O₂) and hydrofluoric acid (HF) can be used to etch a silicon-containing substrate or a silicon-containing layer exposed on a substrate.

In some embodiments, the MacEtch process may etch one or more features within the semiconductor substrate while the one or more metal surfaces of the processing head is positioned in close proximity to the substrate surface and the substrate surface is exposed to the etch solution. A wide variety of features may be etched within the semiconductor substrate. In some embodiments, the MacEtch process may etch one or more vertical holes or trenches within the semiconductor substrate. In other embodiments, the MacEtch process may etch one or more angled holes or trenches within the semiconductor substrate. In yet other embodiments, the MacEtch process may etch one or more horizontal holes or trenches within at least one vertical trench formed within the semiconductor substrate. In still further embodiments, the MacEtch process may etch one or more circular disks within at least one vertical trench formed within the semiconductor substrate. However, the MacEtch process described herein is not strictly limited to etching. In other embodiments, the MacEtch process may smooth the substrate surface while the one or more metal surfaces of the processing head is positioned in close proximity to the substrate surface and the substrate surface is exposed to the etch solution.

According to another embodiment, a wet processing system is provided herein to process a semiconductor substrate. The wet processing system may generally include a substrate support mechanism configured to support a semiconductor substrate, the semiconductor substrate having a substrate surface to be processed; a chemical supply system coupled to supply an etch solution to the substrate surface, the etch solution comprising an oxidant and an etchant; and a processing head having one or more noble metal surfaces, which catalyze local reactions between the etch solution and portions of the substrate surface directly underlying the one or more noble metal surfaces when the one or more noble metal surfaces of the processing head is positioned in close proximity to the substrate surface and the substrate surface is exposed to the etch solution.

In some embodiments, the wet processing system may further include at least one mechanism coupled to the processing head and/or the substrate support mechanism to provide relative movement between the processing head and the semiconductor substrate supported by the substrate support mechanism; and a controller coupled to the chemical supply system and to the at least one mechanism.

The controller may be generally configured to supply: (a) a first set of control signals to the chemical supply system to expose the substrate surface to the etch solution; and (b) a second set of control signals to the at least one mechanism to position the one or more noble metal surfaces of the processing head in close proximity to the substrate surface, while the substrate surface is exposed to the etch solution, to perform a metal assisted chemical etching (MacEtch) process on the substrate surface and/or within the semiconductor substrate. During the MacEtch process, the one or more noble metal surfaces of the processing head may catalyze a reduction of the oxidant and generate free holes, which are injected into portions of the substrate surface directly underlying the one or more noble metal surfaces to form ionic species that are dissolved by the etchant. In some embodiments, the controller may be further configured to supply: (c) a third set of control signals to the at least one mechanism to continue the relative movement between the processing head and the semiconductor substrate during the MacEtch process; and (d) a fourth set of control signals to the at least one mechanism to remove the processing head from the substrate surface upon completion of the MacEtch process.

In some embodiments, the MacEtch process may etch one or more features within the semiconductor substrate. In such embodiments, the third set of control signals supplied to the at least one mechanism may advance the processing head deeper within the one or more of features as the one or more features are being etched to increase a depth of the one or more features. In some embodiments, the one or more features etched within the semiconductor substrate may comprise one or more vertical holes or trenches. In other embodiments, the one or more features etched within the semiconductor substrate may comprise one or more angled holes or trenches.

In some embodiments, the MacEtch process may etch one or more features within at least one vertical trench formed within the semiconductor substrate. In such embodiments, the third set of control signals supplied to the at least one mechanism may translate and/or rotate the processing head within the at least one vertical trench as the one or more features are being etched. In some embodiments, the one or more features etched within the at least one vertical trench may comprise one or more horizontal holes or trenches. In other embodiments, the one or more features etched within the at least one vertical trench may comprise one or more circular disks.

In some embodiments, the MacEtch process may smooth the substrate surface. In such embodiments, the third set of control signals supplied to the at least one mechanism may advance the processing head toward the substrate surface and/or scan the processing head in a lateral direction across the substrate surface as the substrate surface is being smoothed.

In some embodiments, the processing head may include an array of projections that extend from a lower surface of the processing head. In such embodiments, distal ends of the array of projections may be provided with the one or more noble metal surfaces, which catalyze the local reaction between the etch solution and the portions of the substrate surface directly underlying the one or more noble metal surfaces to etch a pattern of features within the semiconductor substrate. The processing head may generally include a one-dimensional (1D) array of projections for etching a 1D pattern of features within the semiconductor substrate, or a two-dimensional (2D) array of projections for etching a 2D pattern of features within the semiconductor substrate. In some embodiments, the array of projections may extend at an angle ranging between 45° and 95° from a lower surface of the processing head. In some embodiments, the array of projections may comprise an array of cylindrical rods or an array of flat plates. In other embodiments, the array of projections may comprise an array of L-shaped rods or plates.

As noted above and described further herein, the present disclosure provides various embodiments of wet processing systems and methods for processing semiconductor substrates. Of course, the order of discussion of the different steps as described herein has been presented for the sake of clarity. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the present invention can be embodied and viewed in many different ways.

Note that this Summary section does not specify every embodiment and/or incrementally novel aspect of the present disclosure or claimed inventions. Instead, the summary only provides a preliminary discussion of different embodiments and corresponding points of novelty over conventional techniques. For additional details and/or possible perspectives of the invention and embodiments, the reader is directed to the Detailed Description section and corresponding figures of the present disclosure as further discussed below.

### BRIEF DESCRIPTION OF THE DRAWINGS

A more complete understanding of the present inventions and advantages thereof may be acquired by referring to the following description taken in conjunction with the accompanying drawings, in which like reference numbers indicate like features. It is to be noted, however, that the accompanying drawings illustrate only exemplary embodiments of the disclosed concepts and are therefore not to be considered limiting of the scope, for the disclosed concepts may admit to other equally effective embodiments.

FIGS. 1A-1C (PRIAR ART) are cross-sectional views through a semiconductor substrate illustrating a conventional metal assisted chemical etching (MacEtch) process used to etch a pattern of features within the semiconductor substrate.

FIG. 2 is a flowchart diagram illustrating one embodiment of a method that utilizes the techniques disclosed herein to process a semiconductor substrate.

FIGS. 3A-3C are cross-sectional views through a semiconductor substrate illustrating one embodiment of a MacEtch process that uses the techniques disclosed herein to etch one or more vertical holes or trenches within a semiconductor substrate.

FIG. 4A is a side view of a processing head that can be used in the MacEtch process shown in FIGS. 3A-3C to form vertical holes or trenches in a semiconductor substrate.

FIG. 4B is a bottom view of the processing head shown in FIG. 4A, according to one embodiment.

FIG. 4C is a bottom view of the processing head shown in FIG. 4A, according to another embodiment.

FIGS. 5A-5C are cross-sectional views through a semiconductor substrate illustrating one embodiment of a MacEtch process that uses the techniques disclosed herein to etch one or more angled holes or trenches within a semiconductor substrate.

FIGS. 6A-6C are cross-sectional views through a semiconductor substrate illustrating one embodiment of a MacEtch process that uses the techniques disclosed herein to etch one or more horizontal holes or trenches within at least one vertical trench formed within the semiconductor substrate.

FIGS. 7A-7C are cross-sectional views through a semiconductor substrate illustrating one embodiment of a MacEtch process that uses the techniques disclosed herein to etch one or more circular disks within at least one vertical trench formed within the semiconductor substrate.

FIGS. 8A-8C are cross-sectional views through a semiconductor substrate illustrating one embodiment of a MacEtch process that uses the techniques disclosed herein to smooth the substrate surface.

FIG. 9A is a cross-sectional view through a semiconductor substrate illustrating another embodiment of a MacEtch process that uses the techniques disclosed herein to smooth the substrate surface.

FIG. 9B is a bottom view of the processing head shown in FIG. 9A.

FIG. 10A is cross-sectional views through a semiconductor substrate illustrating another embodiment of a MacEtch process that uses the techniques disclosed herein to smooth the substrate surface.

FIG. 10B is a bottom view of the processing head shown in FIG. 10A.

FIG. 11A is a cross-sectional view through a semiconductor substrate illustrating another embodiment of a MacEtch process that uses the techniques disclosed herein to smooth the substrate surface.

FIG. 11B is a bottom view of the processing head shown in FIG. 11A in accordance with one embodiment.

FIG. 11C is a bottom view of the processing head shown in FIG. 11A in accordance with another embodiment.

FIG. 12 illustrates one embodiment of a wet processing system that utilizes the techniques disclosed herein to process a semiconductor substrate.

FIG. 13 illustrates another embodiment of a wet processing system that utilizes the techniques disclosed herein to process a semiconductor substrate.

FIG. 14 illustrates yet another embodiment of a wet processing system that utilizes the techniques disclosed herein to process a semiconductor substrate.

### DETAILED DESCRIPTION

The present disclosure provides various embodiments of wet processing systems and methods that utilize metal assisted chemical etching (MacEtch) to process a semiconductor substrate. Unlike conventional MacEtch processes, the systems and methods disclosed herein utilize a processing head having one or more metal surfaces (otherwise referred to herein as a metal-coated processing head) to catalyze the MacEtch reactions that occur at the interface between the metal surface(s) of the processing head and the surface of a semiconductor substrate when the substrate surface is exposed to an etch solution.

The metal-coated processing head can be used to perform a wide variety of MacEtch processes on the substrate surface and/or within the semiconductor substrate. For example, the metal-coated processing head can be used to catalyze MacEtch reactions when: (a) etching one or more features (e.g., one or more holes, trenches, circular disks, etc.) within the semiconductor substrate, or (b) removing high point(s) on substrate surface to smooth the substrate surface. The embodiments disclosed herein eliminate variations in etching direction by controlling movement of the metal-coated processing head and/or the semiconductor substrate, as the feature(s) are being etched or the substrate surface is being smoothed. In doing so, the disclosed embodiments provide significantly greater control over the etching process compared to conventional MacEtch processes, which rely on noble metal patterns deposited onto the substrate surface. The greater etching control enables the embodiments disclosed herein to form deep, straight holes and trenches within the semiconductor substrate, as well as unique structures (such as, e.g., angled holes and trenches, and horizontal holes, trenches or circular disks etched within vertically oriented trenches), which cannot be formed using conventional MacEtch processes.

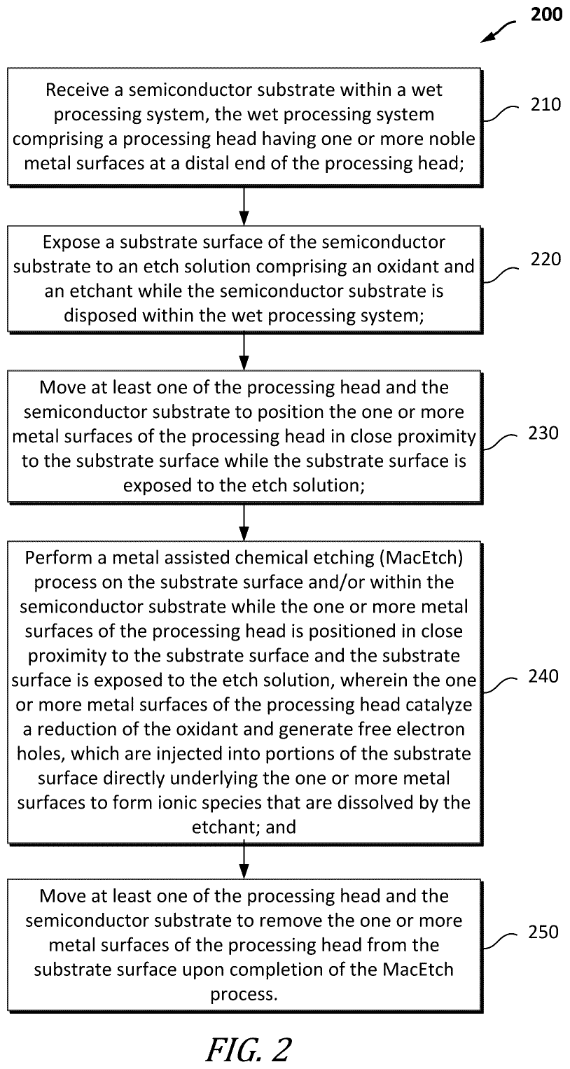

FIG. 2 illustrates one embodiment of a method 200 that utilizes the techniques disclosed herein to process a semiconductor substrate. It will be recognized that the embodiment of the method 200 is merely exemplary and additional methods may utilize the techniques disclosed herein. Further, additional processing steps may be added to the method 200 as the steps described are not intended to be exclusive. Moreover, the order of the steps is not limited to the order shown in the figures as different orders may occur and/or various steps may be performed in combination or at the same time.

The method 200 uses metal assisted chemical etching (MacEtch) to process semiconductor substrates. The MacEtch process can be performed on a wide variety of semiconductor substrates. In one embodiment, the semiconductor substrate may be a base semiconductor substrate or a base layer of semiconductor material. In another embodiment, the substrate may be a semiconductor substrate having one or more semiconductor processing layers (all of which together may comprise the substrate) formed thereon. Thus, in one embodiment, the semiconductor substrate may be a semiconductor wafer that has been subject to multiple semiconductor processing steps which yield a wide variety of structures and layers, all of which are known in the substrate processing art, and which may be considered to be part of the substrate.

As shown in FIG. 2, the method 200 may begin by receiving a semiconductor substrate within a wet processing system (in step 210). The wet processing system includes a processing head having one or more metal surfaces at a distal end of the processing head. The wet processing system may also include other components, such as a substrate support mechanism for supporting the semiconductor substrate, a chemical supply system for supplying liquids (such as, e.g., an etch solution) to the semiconductor substrate, and a controller for controlling the supply of liquids to the substrate and the movement of the processing head and/or the substrate, as described in more detail below.

In the method 200, a surface of the semiconductor substrate is exposed to an etch solution comprising an oxidant and an etchant while the semiconductor substrate is disposed within the wet processing system (in step 220). The processing head and/or the semiconductor substrate is moved to position the one or more metal surfaces of the processing head in close proximity to the substrate surface (in step 230) while the substrate surface is exposed to the etch solution (in step 220). A metal assisted chemical etching (MacEtch) process is performed on the substrate surface and/or within the semiconductor substrate (in step 240) while the one or more metal surfaces of the processing head is positioned in close proximity to the substrate surface and the substrate surface is exposed to the etch solution. During the MacEtch process, the one or more metal surfaces of the processing head catalyze a reduction of the oxidant and generate free holes, which are injected into portions of the substrate surface directly underlying the one or more metal surfaces to form ionic species that are dissolved by the etchant. Upon completion of the MacEtch process, the processing head and/or the semiconductor substrate is moved to remove the one or more metal surfaces of the processing head from the substrate surface (in step 250).

The MacEtch process performed in step 240 of method 200 may be performed on a wide variety of semiconductor materials. Examples of materials on which the MacEtch process may be performed include, but are not limited to, silicon (Si), silicon carbide (SiC), silicon germanium (SiGe) and III-V compound semiconductor materials, such as gallium arsenide (GaAs) and gallium nitride (GaN). The etch solution provided to the substrate surface depends on the semiconductor material being etched. For example, etch solutions containing an oxidant and an etchant (e.g., an acid, base or water) are commonly used to etch silicon-containing materials. Examples of oxidants that may be used to etch silicon-containing materials include, but are not limited to, hydrogen peroxide (H₂O₂), nitric acid (HNO₃), potassium persulfate (K₂S₂O₈), oxygen (O₂) dissolved in water (H₂O) and ozonated water. Examples of etchants include, but are not limited to, hydrofluoric acid (HF), sulfuric acid (H₂SO₄), potassium hydroxide (KOH) and deionized water (H₂O). In one example embodiment, an etch solution containing a mixture of hydrogen peroxide (H₂O₂) and hydrofluoric acid (HF) can be used to etch a silicon-containing substrate or a silicon-containing layer exposed on a substrate.

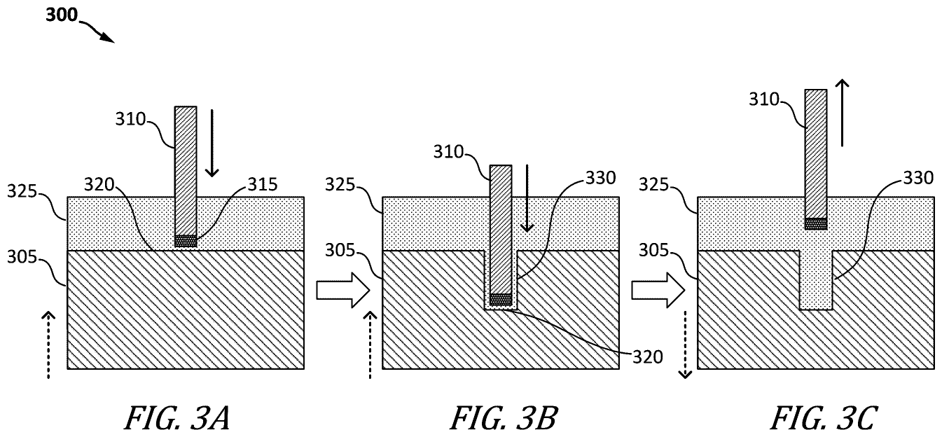

The processing head provided within the wet processing system may include a wide variety of metal surface(s) and configurations. Non-exclusive examples of processing heads having one or more metal surfaces are shown in FIGS. 3-11 and described in more detail below. In some embodiments, noble metals such as gold (Au), silver (Ag), platinum (Pt), palladium (Pd), ruthenium (Ru), rhodium (Rh), osmium (Os) and iridium (Ir) may be provided on the processing head. The noble metal surface(s) provided on the processing head catalyze the MacEtch reactions (e.g., the reduction and oxidation reactions) that occur at the interface between the noble metal surface(s) of the processing head and the surface of a semiconductor substrate when the substrate surface is exposed to the etch solution. In other embodiments, other metals such as iron (Fe), nickel (Ni), copper (Cu) and aluminum (Al) can also act as a catalyst in the MacEtch process.

The metal surface(s) provided on the processing head catalyze the reduction of the oxidant in the etch solution and generate free electron holes (h+) at the interface between the metal surface(s) and portions of the substrate surface directly underlying the metal surface(s). The free electron holes (h+) generated at the metal-semiconductor interface are injected into the valence band of the portions of the substrate surface directly underlying the metal surface(s) to weaken chemical bonds (e.g., Si—Si bonds) and form ionic species that are dissolved by the etchant. The etchant attacks the weakened bonds to dissolve the underlying portions of the substrate surface and increase the local dissolution rate at which the underlying portions of the substrate surface are dissolved within the etch solution. As a result, the portions of the substrate surface directly underlying the metal surface(s) of the processing head are preferentially etched, compared to portions of the substrate surface not underlying the metal surface(s).

The MacEtch process performed in step 240 of method 200 may generally depend on the type of metal (e.g., Au, Ag, Pt, etc.) provided on the processing head, the configuration of the metal surfaces provided on the processing head (e.g., a single metal surface vs. a pattern of metal surfaces), the oxidant and etchant included within the etch solution, the etchant concentration and the substrate surface being etched.

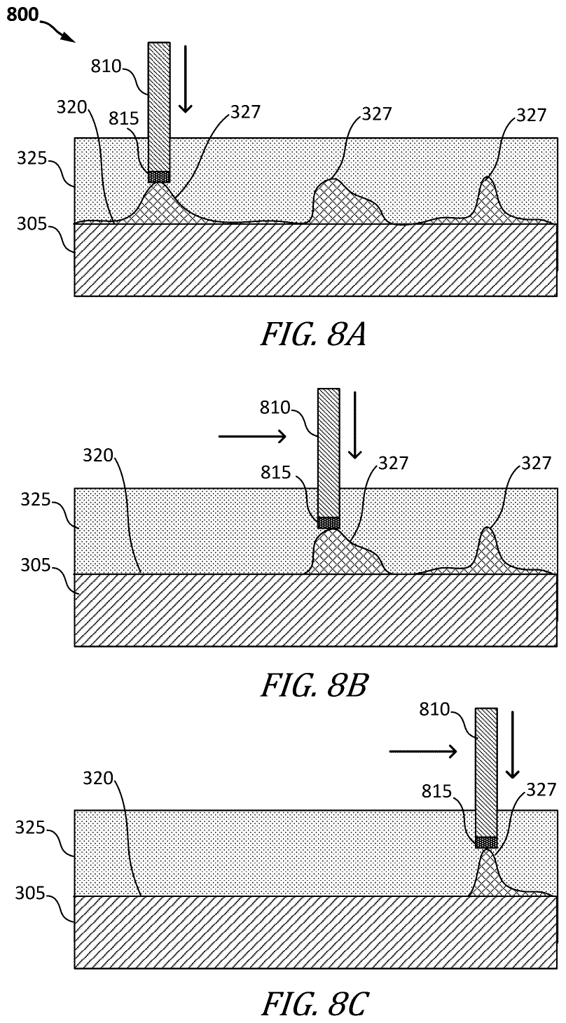

The method 200 shown in FIG. 2 can perform a wide variety of MacEtch processes on the substrate surface and/or within the semiconductor substrate (in step 240) by providing the metal surface(s) used to catalyze MacEtch reactions on the processing head, rather than depositing the metal catalyst on the substrate surface being etched. In some embodiments, the processing head described herein can be used to etch one or more features within the semiconductor substrate while the processing head is positioned in close proximity to the substrate surface and the substrate surface is exposed to the etch solution. FIGS. 3-7 provide examples of MacEtch processes and processing head configurations that can be used to etch various features (e.g., holes, trenches, circular disks, etc.) within the semiconductor substrate in step 240. In other embodiments, the processing head described herein can be used to smooth the substrate surface, while the processing head is positioned in close proximity to the substrate surface and the substrate surface is exposed to the etch solution. FIGS. 8-11 provide additional examples of MacEtch processes and processing head configurations that can be used to smooth the substrate surface in step 240. It is noted that while various examples are provided in FIGS. 3-11, other processing head configurations can be used to perform other MacEtch processes on/within a semiconductor substrate.

FIGS. 3A-3C illustrate one embodiment of a MacEtch process 300 that uses the techniques described herein to etch one or more vertical holes or trenches within a semiconductor substrate 305. The semiconductor substrate 305 may comprise a wide variety of materials to be etched, including silicon-containing materials (such as, e.g., Si, SiC, SiGe, etc.) and III-V compound semiconductor materials (such as, e.g., GaAs and GaN). In one embodiment, the semiconductor substrate 305 may comprise silicon (Si) or contain a Si layer at the substrate surface 320.

The MacEtch process 300 begins in FIG. 3A by moving a processing head 310 in close proximity to the substrate surface 320 of the semiconductor substrate 305, while the substrate surface 320 is exposed to an etch solution 325. Alternatively, the semiconductor substrate 305 can be moved in close proximity to the processing head 310 in FIG. 3A, while the substrate surface 320 is exposed to the etch solution 325. The etch solution 325 supplied to the substrate surface 320 may generally include an oxidant and an etchant. In one embodiment, the etch solution 325 may include a mixture of hydrogen peroxide (H₂O₂) and hydrofluoric acid (HF) when etching silicon-containing materials.

In the embodiment shown in FIG. 3A, at least one metal surface 315 (e.g., a noble metal surface) is provided at the distal end of the processing head 310. When the metal surface 315 is positioned in close proximity to the substrate surface 320, the metal surface 315 catalyzes local reactions (e.g., the reduction and oxidation reactions) between the etch solution 325 and the portions of substrate surface 320 underlying the metal surface 315. When hydrogen peroxide (H₂O₂) is used as the oxidant, the reduction reaction at the metal-substrate interface can be expressed as H₂O₂+2H+→2H₂O+2h⁺. The generated free electron holes (h⁺) are injected into the underlying substrate surface 320 to weaken the chemical bonds (e.g., Si—Si bonds) and form ionic species at the underlying substrate surface 320 that are dissolved by the etchant to etch the underlying substrate surface 320. When hydrofluoric acid (HF) is used as the etchant, the dissolution reaction at the metal-substrate interface can be expressed as Si+6HF+4h⁺→SiF₆²⁻6H⁺. Other reduction and dissolution reactions may occur when using other oxidants and etchants in the etch solution 325.

During the MacEtch process 300, the processing head 310 and/or the semiconductor substrate 305 is/are moved in FIG. 3B (e.g., continually or periodically), as the substrate surface 320 is being etched, to ensure that the metal surface 315 of the processing head 310 remains in close proximity to the substrate surface 320 during the etch process. In the embodiment shown in FIG. 3B, the processing head 310 and/or the semiconductor substrate 305 is/are moved in a direction perpendicular to the substrate surface 320 to etch one or more vertical holes or trenches 330 within the semiconductor substrate 305. The relative movement between the processing head 310 and the semiconductor substrate 305 may continue to advance the processing head 310 deeper within the one or more of vertical holes or trenches 330, as the holes or trenches 330 are being etched, to increase a depth of the etched features. In some embodiments, the processing head 310 and/or the semiconductor substrate 305 may be moved within the etched features, as the features are being etched, to ensure the etch solution 325 remains in contact with the substate surface 320 and to allow etch by-products to move out of the etched features into the bulk solution. Once a desired depth is achieved and the MacEtch process 300 is complete, the processing head 310 and/or the semiconductor substrate 305 is/are moved to remove the processing head 310 from the substrate surface 320, as shown in FIG. 3C.

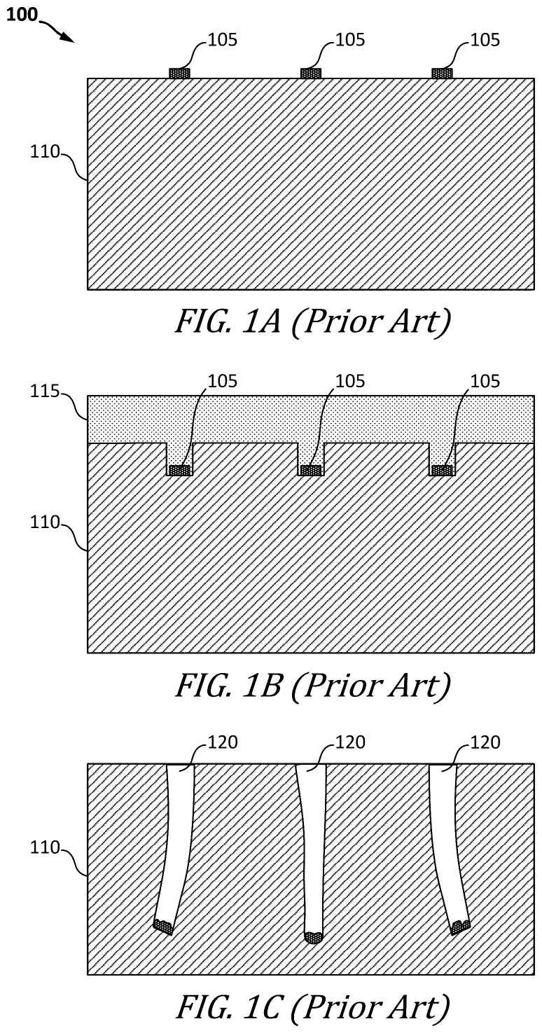

The MacEtch process 300 provides various advantages over the conventional MacEtch process 100 shown in FIGS. 1A-1C. Unlike the conventional MacEtch process 100, which deposits a metal catalyst on the substrate surface to be etched, the MacEtch process 300 provides the metal catalyst on a distal end of the processing head 310. The MacEtch process 300 accurately controls the etch depth and direction by providing the metal catalyst on the processing head 310 and controlling the relative movement between the processing head 310 and the semiconductor substrate 305. This enables the MacEtch process 300 to form the deep, straight vertical holes and trenches (and other features), which are difficult (or not possible) to form using conventional MacEtch processes. In addition to providing significantly greater control over the etch process, the MacEtch process 300 eliminates the subsequent processing steps typically performed after conventional MacEtch processes to remove the metal catalyst from the etched features.

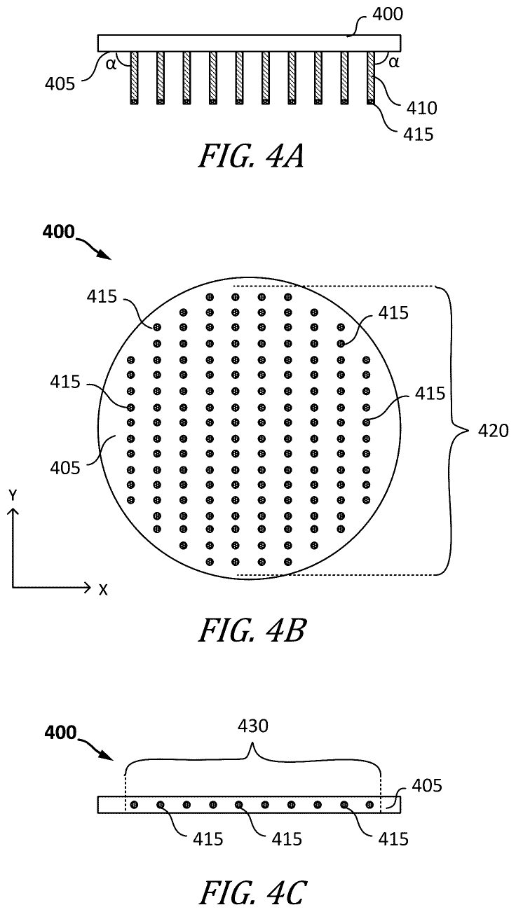

FIGS. 4A-4C illustrate example embodiments of a processing head 400 that can be used in the MacEtch process 300 to form vertical holes or trenches 330 in the semiconductor substrate 305. FIG. 4A illustrates a side view of the processing head 400 having a plurality of projections 410, which extend at an angle (α) of approximately 90° from a lower surface 405 of the processing head 400. The projections 410 may include a plurality of cylindrical rods (to form holes) or a plurality of flat plates (to form trenches). Distal ends of the projections 410 are provided with metal surfaces 415 (e.g., noble metal surfaces), which catalyze the local reaction between the etch solution 325 and the portions of the substrate surface 320 underlying the metal surfaces 415 to etch the holes or trenches 330 within the semiconductor substrate 305.

In some embodiments, the processing head 400 shown in FIG. 4A may include a two-dimensional (2D) array of projections 420, as shown for example in FIG. 4B. In other embodiments, the processing head 400 shown in FIG. 4A may include a one-dimensional (1D) array of projections 430, as shown for example in FIG. 4C. The projections 420/430 may comprise a plurality of cylindrical rods, each having a metal surface 415 at a distal end thereof. In order to form vertical holes, the cylindrical rods may extend at an angle (α) of approximately 90° (e.g., an angle ranging between 85° and) 95° from a lower surface 405 of the processing head 400. The dimensions (e.g., diameter and length) of the cylindrical rods, as well as the spacing between the rods, may be selected so as to form holes of a desired diameter and depth.

In some embodiments, the processing head 400 shown in FIG. 4B may be positioned in close proximity to the substrate surface 320 in the presence of the etch solution 325 to etch a 2D pattern of vertical holes within the semiconductor substrate 305. The 2D pattern of vertical holes may be formed by moving the processing head 400 and/or the semiconductor substrate 305 in a direction perpendicular to the substrate surface 320, as shown in FIG. 3B and discussed above. In some embodiments, the processing head 400 shown in FIG. 4C may be used to etch a 1D pattern of vertical holes (e.g., a row or column of vertical holes) within the semiconductor substrate 305 by moving the processing head 400 and/or the semiconductor substrate 305 in a direction perpendicular to the substrate surface 320, as shown in FIG. 3B and discussed above. In some embodiments, a 2D pattern of vertical holes may be etched using the processing head 400 shown in FIG. 4C by moving the processing head 400 to a new location on the semiconductor substrate 305 after each row or column of holes is formed.

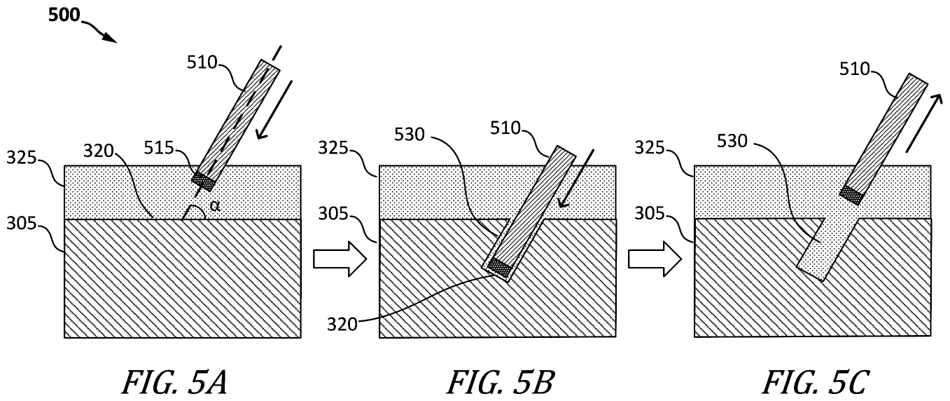

The embodiments disclosed above provide improved MacEtch processes and processing head configurations for etching vertical holes (or trenches) within a semiconductor substrate. However, the techniques disclosed herein are not strictly limited to vertical holes (or trenches), and may be used to etch other features within a semiconductor substrate. Examples of other features that may be etched within a semiconductor substrate using the techniques disclosed herein are shown in FIGS. 5-7.

FIGS. 5A-5C illustrate one embodiment of a MacEtch process 500 that uses the techniques disclosed herein to etch one or more angled holes or trenches within a semiconductor substrate 305. Like the previous embodiment, the MacEtch process 500 utilizes a processing head 510 having at least one metal surface 515 to catalyze local reactions between the etch solution 325 and the portions of substrate surface 320 directly underlying the metal surface 515 and form ionic species, which are dissolved in the etch solution 325 to etch the underlying substrate surface 320.

The MacEtch process 500 begins in FIG. 5A by positioning the processing head 510 in close proximity to the substrate surface 320 of the semiconductor substrate 305, while the substrate surface 320 is exposed to the etch solution 325. As the substrate surface 320 is being etched, the MacEtch process 500 moves the processing head 510 and/or the semiconductor substrate 305 in FIG. 5B to ensure that the metal surface 515 of the processing head 510 remains in close proximity to the substrate surface 320 as the substrate surface 320 is being etched.

Unlike the previous embodiment, the processing head 510 is uniquely configured to etch one or more angled holes or trenches 530 within the semiconductor substrate 305. In some embodiments, the one or more angled holes or trenches 530 may be etched within the semiconductor substrate 305 by moving the processing head 510 and/or the semiconductor substrate 305 in a direction, which is not perpendicular to the substrate surface 320. For example, the processing head 510 may be directed towards the semiconductor substrate 305 at an acute angle (α) relative to the substrate surface 320, as depicted in FIG. 5A. The acute angle (α) may range, for example, between 45° and 85°. In other embodiments, the one or more angled holes or trenches 530 may be etched within the semiconductor substrate 305 by: (a) providing the processing head 510 with an array of projections, which extend at an acute angle (α) from a lower surface of the processing head 510, and (b) moving the processing head 510 and/or the semiconductor substrate 305 in a direction perpendicular to the substrate surface 320. For example, the processing head 400 shown in FIG. 4A can be modified so that the array of projections 410 extend at an acute angle (α) ranging between 45° and 85° from the lower surface 405 of the processing head 400.

The MacEtch process 500 may continue to advance the processing head 510 deeper within the one or more angled holes or trenches 530, as the holes or trenches are being etched, to increase a depth of the etched features. In some embodiments, the processing head 510 and/or the semiconductor substrate 305 may be moved within the etched features, as the features are being etched, to ensure the etch solution 325 remains in contact with the substate surface 320 and to allow etch by-products to move out of the etched features into the bulk solution. Once a desired depth is achieved and the MacEtch process 500 is complete, the processing head 510 and/or the semiconductor substrate 305 may be moved to remove the processing head 510 from the substrate surface 320, as shown in FIG. 5C.

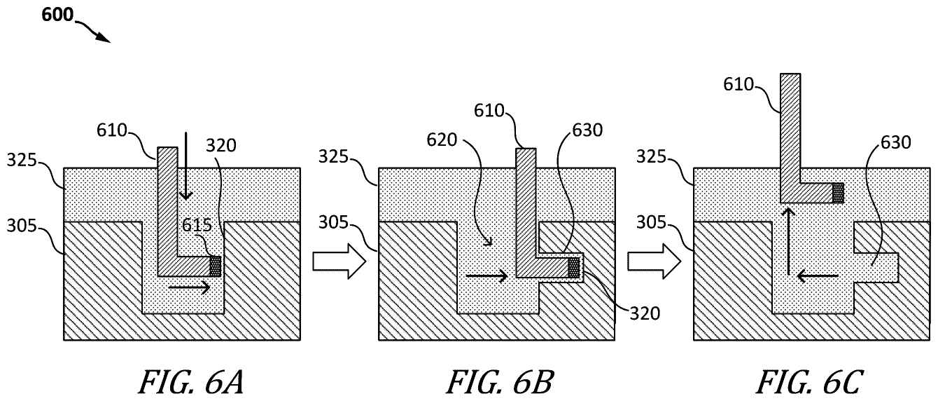

FIGS. 6A-6C illustrate one embodiment of a MacEtch process 600 that uses the techniques disclosed herein to etch one or more horizontal holes or trenches within at least one vertical trench formed within a semiconductor substrate 305. Like the previous embodiments, the MacEtch process 600 utilizes a processing head 610 having at least one metal surface 615 to catalyze local reactions between the etch solution 325 and the portions of substrate surface 320 directly underlying the metal surface 615 and form ionic species, which are dissolved in the etch solution 325 to etch the underlying substrate surface 320.

The MacEtch process 600 begins in FIG. 6A by positioning the processing head 610 in close proximity to the substrate surface 320 of the semiconductor substrate 305, while the substrate surface 320 is exposed to the etch solution 325. As the substrate surface 320 is being etched, the MacEtch process 600 moves the processing head 610 and/or the semiconductor substrate 305 in FIG. 6B to ensure that the metal surface 615 of the processing head 610 remains in close proximity to the substrate surface 320 as the substrate surface 320 is being etched.

Unlike the previous embodiments, the processing head 610 is uniquely configured to etch to etch one or more horizontal holes or trenches 630 within at least one vertical trench 620 formed within the semiconductor substrate 305. In some embodiments, the one or more horizontal holes or trenches 630 may be etched within the at least one vertical trench 620 by: (a) providing the processing head 610 with an array of L-shaped projections (e.g., an array of L-shaped rods or plates), and (b) moving the processing head 610 and/or the semiconductor substrate 305 in a direction perpendicular to the substrate surface 320 being etched (e.g., the sidewall of the vertical trench 620).

The MacEtch process 600 may continue to advance the processing head 610 deeper within the one or more horizontal holes or trenches 630, as the holes or trenches are being etched, to increase a horizontal depth of the etched features. In some embodiments, the processing head 610 and/or the semiconductor substrate 305 may be moved within the etched features, as the features are being etched, to ensure the etch solution 325 remains in contact with the substate surface 320 and to allow etch by-products to move out of the etched features into the bulk solution. Once a desired depth is achieved and the MacEtch process 600 is complete, the processing head 610 and/or the semiconductor substrate 305 may be moved to remove the processing head 610 from the substrate surface 320, as shown in FIG. 6C.

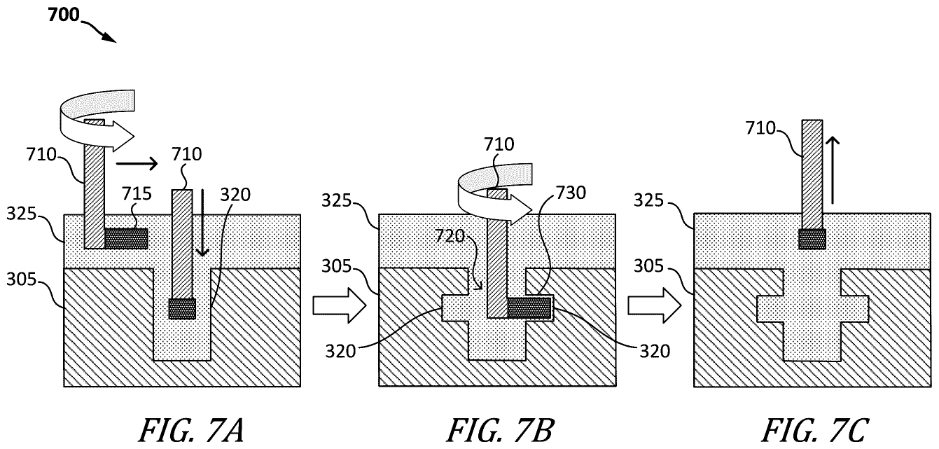

FIGS. 7A-7C illustrate one embodiment of a MacEtch process 700 that uses the techniques disclosed herein to etch one or more circular disks within at least one vertical trench formed within a semiconductor substrate 305. Like the previous embodiments, the MacEtch process 700 utilizes a processing head 710 having at least one metal surface 715 to catalyze local reactions between the etch solution 325 and the portions of substrate surface 320 directly underlying the metal surface 715 and form ionic species, which are dissolved in the etch solution 325 to etch the underlying substrate surface 320.

The MacEtch process 700 begins in FIG. 7A by positioning the processing head 710 in close proximity to the substrate surface 320 of the semiconductor substrate 305, while the substrate surface 320 is exposed to the etch solution 325. As the substrate surface 320 is being etched, the MacEtch process 700 moves the processing head 710 and/or the semiconductor substrate 305 in FIG. 7B to ensure that the metal surface 715 of the processing head 710 remains in close proximity to the substrate surface 320 as the substrate surface 320 is being etched.

Unlike the previous embodiments, the processing head 710 is configured to etch one or more circular disks 730 within at least one vertical trench 720 formed within the semiconductor substrate 305. In some embodiments, the one or more circular disks 730 may be etched within the at least one vertical trench 720 by: (a) providing the processing head 710 with one or more L-shaped projections (e.g., L-shaped rods or plates), and (b) rotating the processing head 710 within the at least one vertical trench 720 as the substrate surface 320 is being etched.

The MacEtch process 700 may continue to rotate the processing head 710 at least 360° to form the one or more circular disks 730 within the at least one vertical trench 720. Once the one or more circular disks 730 are formed and the MacEtch process 700 is complete, the processing head 710 and/or the semiconductor substrate 705 may be moved to remove the processing head 710 from the substrate surface 320, as shown in FIG. 7C.

The embodiments disclosed above provide improved MacEtch processes and processing head configurations for etching a wide variety of features within a semiconductor substrate. However, the techniques disclosed herein are not strictly limited to etching features within a substrate, and may alternatively be used to remove high point(s) on substrate surface to smooth the substrate surface. Examples of MacEtch processes and processing head configurations that use the techniques disclosed herein to smooth the substrate surface are shown in FIGS. 8-11.

Some semiconductor processes may cause the substrate surface 320 to have a rough surface, which needs to be smoothed. FIGS. 8A-8C illustrate one embodiment of a MacEtch process 800 that uses the techniques disclosed herein to smooth a rough surface of a semiconductor substrate 305 by etching or removing the high points 327 on the substrate surface 320. Like the previous embodiments, the MacEtch process 800 utilizes a processing head 810 having at least one metal surface 815 to catalyze local reactions between the etch solution 325 and the portions of substrate surface 320 directly underlying the metal surface 815 and form ionic species, which are dissolved in the etch solution 325 to etch the underlying substrate surface 320.

The surface topography of the semiconductor substrate can be measured to determine the location of the high points 327 on the substrate surface prior to performing the MacEtch process 800. Once the locations of the high points 327 are determined, MacEtch process 800 may expose the substrate surface to an etch solution 325 and position the processing head 810 in close proximity to one of the high point 327 locations identified on the substrate surface 320 (as shown in FIG. 8A). The high point 327 is etched much faster than the substrate surface 320, due to the metal catalyst provided on the distal end of the processing head 810. As the high point 327 is being etched, the MacEtch process 800 moves the processing head 810 and/or the semiconductor substrate 305 in a direction perpendicular to the substrate surface 320 to ensure that the metal surface 815 of the processing head 810 remains in close proximity to the high point 327 until the high points 327 are removed.

After each high point 327 is removed from the substrate surface 320, the MacEtch process 800 scans the processing head 810 and/or the semiconductor substrate 305 in a lateral direction across the substrate surface 320 to position the processing head 810 above a new high point 327 on the substrate surface 320 (as shown in FIGS. 8B and 8C). In some embodiments, an algorithm may be generated based on the surface topography measurement to determine the dwelling time and location of the processing head 810 needed to remove the high points 327 from the substrate surface 320.

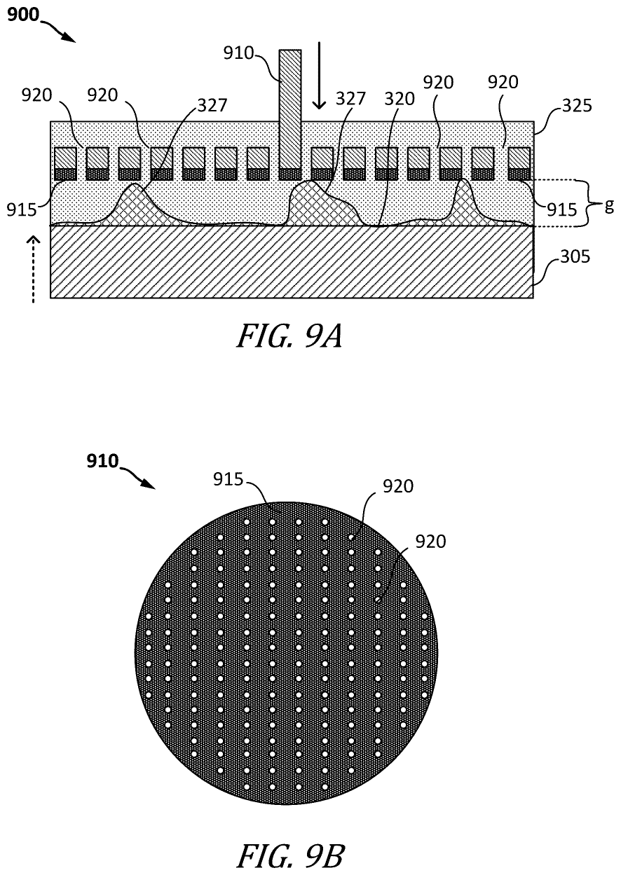

The embodiment disclosed above in FIGS. 8A-8C provides a unique method that utilizes metal-assisted chemical etching (MacEtch) to smooth a rough substrate surface. In the MacEtch process 800, the processing head 810 is translated across the substrate surface 320 to individually remove each of the high points 327 identified on the substrate surface 320. The MacEtch process 800 is somewhat time consuming and requires pre-measurement of the substrate surface 320. Alternative embodiments of MacEtch processes and processing head configurations for smoothing a rough substrate surface are shown in FIGS. 9-11.

FIG. 9A illustrates another embodiment of a MacEtch process 900 that uses the techniques disclosed herein to smooth a rough surface of a semiconductor substrate 305 by etching or removing the high points 327 on the substrate surface 320. Like the previous embodiment, the MacEtch process 900 utilizes a processing head 910 having at least one metal surface 915 to catalyze local reactions between the etch solution 325 and the portions of substrate surface 320 directly underlying the at least one metal surface 915 and form ionic species, which are dissolved in the etch solution 325 to etch the underlying substrate surface 320.

The MacEtch process 900 begins in FIG. 9A by positioning the processing head 910 near the high points 327 on the substrate surface 320 while the substrate surface is exposed to the etch solution 325. The high points 327 are etched much faster than the substrate surface 320, due to the metal catalyst (i.e., the at least one metal surface 915) provided on the distal end of the processing head 910. As the high points 327 are being etched, the MacEtch process 900 moves the processing head 910 and/or the semiconductor substrate 305 in a direction perpendicular to the substrate surface 320 to ensure that the at least one metal surface 915 of the processing head 910 remains in close proximity to the high points 327 until the high points 327 are removed.

Unlike the processing head 810, which is designed to target individual locations on the substrate, the processing head 910 used in the MacEtch process 900 is comprises a relatively large, flat surface. In some embodiments, the processing head 910 may be disk-shaped, as shown in FIG. 9B. The diameter of the disk-shaped processing head 910 may be substantially equal to the diameter the semiconductor substrate 305, in some embodiments. As shown in FIGS. 9A and 9B, the underside of the processing head 910 is provided with the at least one metal surface 915 (e.g., a noble metal surface), which catalyzes the MacEtch reactions (e.g., the reduction and oxidation reactions) that occur at the interface between the at least one metal surface 915 of the processing head 910 and the surface of the semiconductor substrate 305 when the substrate surface 320 is exposed to the etch solution 325. A plurality of openings 920 are provided within the processing head 910 to allow mass transfer of liquids and etch by-products removed from the substrate surface 320.

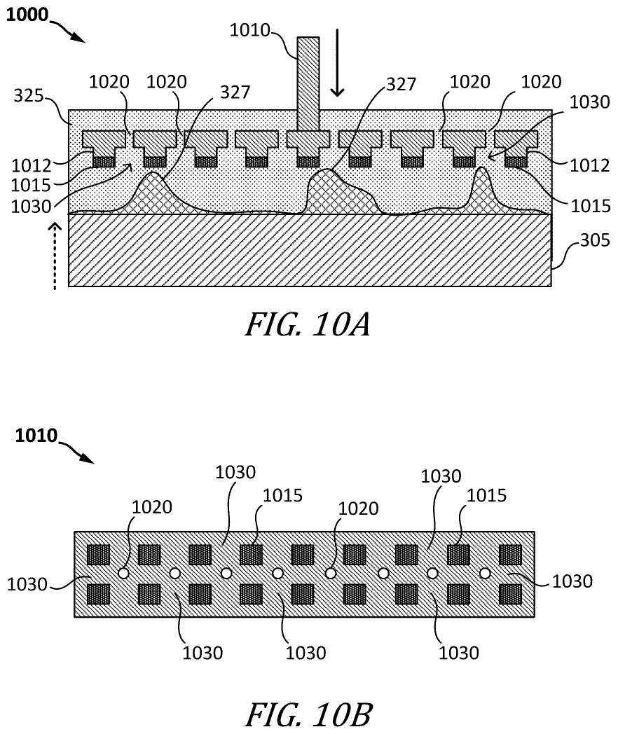

The gap (g) between the at least one metal surface 915 provided on the processing head 910 and the substrate surface 320 is typically very small. In some embodiments, the gap (g) may not provide sufficient space for the etch solution 325 to flow between the two surfaces. FIGS. 10A and 10B illustrate alternative embodiments of MacEtch processes and processing head configurations that use the techniques disclosed herein to smooth a rough surface of a semiconductor substrate 305 by etching the high points 327 on the substrate surface 320. Like the previous embodiments, the MacEtch process 1000 utilizes a processing head 1010 having at least one metal surface 1015 to catalyze local reactions between the etch solution 325 and the portions of substrate surface 320 directly underlying the at least one metal surface 1015 and form ionic species, which are dissolved in the etch solution 325 to etch the underlying substrate surface 320.

The MacEtch process 1000 begins in FIG. 10A by positioning the processing head 1010 near the high points 327 on the substrate surface 320 while the substrate surface is exposed to the etch solution 325. The high points 327 are etched much faster than the substrate surface 320, due to the metal catalyst (i.e., the at least one metal surface 1015) provided on the distal end of the processing head 1010. As the high points 327 are etched, the MacEtch process 1000 moves the processing head 1010 and/or the semiconductor substrate 305 in a direction perpendicular to the substrate surface 320 to ensure that the at least one metal surface 1015 of the processing head 1010 remains in close proximity to the high points 327 until the high points 327 are removed.

As shown in FIGS. 10A and 10B, the processing head 1010 comprises a plurality of projections 1012, which extend from a lower surface of the processing head 1010. A distal end of each projection 1012 is provided with a metal surface 1015 (e.g., a noble metal surface), which catalyzes the MacEtch reactions (e.g., the reduction and oxidation reactions) that occur at the interface between the metal surface 1015 of the processing head 1010 and the surface of the semiconductor substrate 305 when the substrate surface 320 is exposed to the etch solution 325. A plurality of openings 1020 are provided within the processing head 1010 to allow mass transfer of liquids and etch by-products removed from the substrate surface 320.

Unlike the processing head 910, which is implemented as a relatively flat, circular disk, the processing head 1010 used in the MacEtch process 1000 includes a plurality of metal-coated projections 1012 that extend from the lower surface of the processing head 1010, forming cavities 1030 on the underside of the processing head 1010. The cavities 1030 surrounding the metal-coated projections 1012 provide space for the etch solution 325 to flow between the metal-coated projections 1012 and the substrate surface 320.

The embodiments disclosed above in FIGS. 8A-8C, 9A-9B and 10A-10B utilize MacEtch techniques for smoothing rough surfaces, rather than etching features within a semiconductor substrate. In the embodiments disclosed above, contact between the metal surface(s) of the processing head and the high points 327 on the substrate surface 320 is maintained during the MacEtch process by moving the processing head and/or the semiconductor substrate 305 in a direction perpendicular to the substrate surface 320 as the high points 327 are being etched. Some of these processes may be more successful when the semiconductor substrate 305 is held stationary and immersed within the etch solution 325, and thus, may not adapt well to spin chambers.

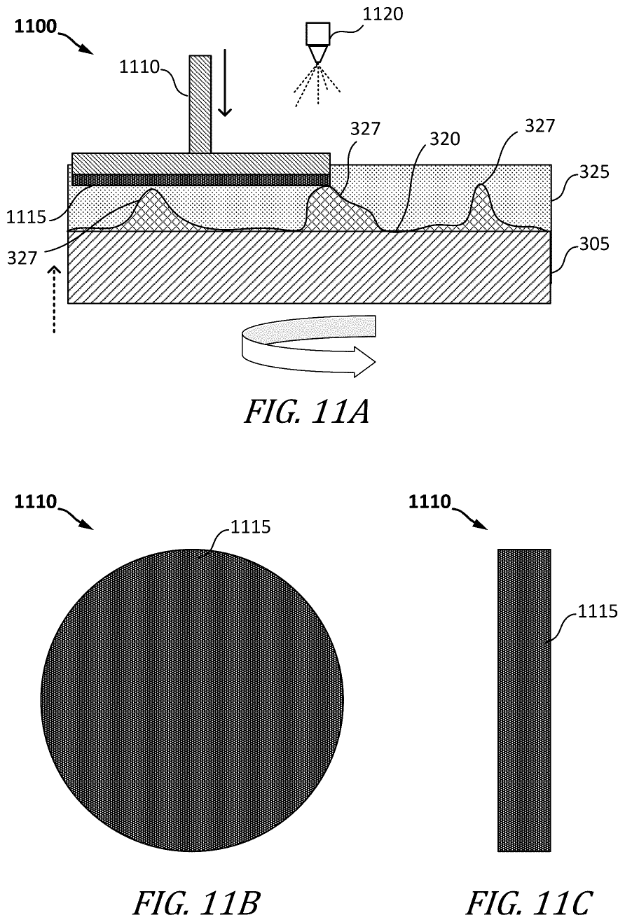

FIGS. 11A-11C illustrate alternative embodiments of MacEtch processes and processing head configurations that use the techniques disclosed herein to smooth a rough surface of a semiconductor substrate 305 by etching the high points 327 on the substrate surface 320. Like the previous embodiments, the MacEtch process 1100 utilizes a processing head 1110 having at least one metal surface 1115 to catalyze local reactions between the etch solution 325 and the portions of substrate surface 320 directly underlying the at least one metal surface 1115 and form ionic species, which are dissolved in the etch solution 325 to etch the underlying substrate surface 320.

Unlike the previous embodiments shown in FIGS. 8A-8C, 9A-9B and 10A-10B, the processing head 1110 is a flat disk (FIG. 11B) or bar (FIG. 11C). The underside of the processing head 1110 is provided with a metal surface 1115 (e.g., a noble metal surface). In the example embodiment shown in FIG. 11A, the disk or bar-shaped processing head 1110 is smaller than the semiconductor substrate 305. In other embodiments, the diameter (or length) of the processing head 1110 may be substantially equal to the diameter the semiconductor substrate 305.

In the MacEtch process 1100 shown in FIG. 11A, the etch solution 325 is dispensed onto the substrate surface 320 via a liquid nozzle 1120 while the semiconductor substrate 305 is rotated (e.g., by a spin chuck). Alternatively, the processing head 1110 may be rotated, while the semiconductor substrate 305 is held stationary. The processing head 1110 is positioned near the high points 327 on the substrate surface 320 while the etch solution 325 is dispensed onto the substrate surface 320. The high points 327 are etched much faster than the substrate surface 320, due to the metal catalyst (i.e., the at least one metal surface 1115) provided on the distal end of the processing head 1010. As the high points 327 are etched, the MacEtch process 1100 moves the processing head 1110 and/or the semiconductor substrate 305 in a direction perpendicular to the substrate surface 320 to ensure that the at least one metal surface 1115 of the processing head 1110 remains in close proximity to the high points 327 until the high points 327 are removed.

The MacEtch process 1100 shown in FIGS. 11A-11C utilizes MacEtch and chemical mechanical polishing (CMP) techniques to smooth the rough surfaces on a semiconductor substrate. In some embodiments, the high points 327 on the substrate surface 320 can be removed by moving the processing head 1110 in a direction perpendicular to the substrate surface 320, while the semiconductor substrate 305 is rotated by a spin chuck and the etch solution 325 is continuously dispensed onto the substrate surface 320 by a liquid nozzle 1120. Thus, the MacEtch process 1100 may be particularly well-suited to spin processing chambers.

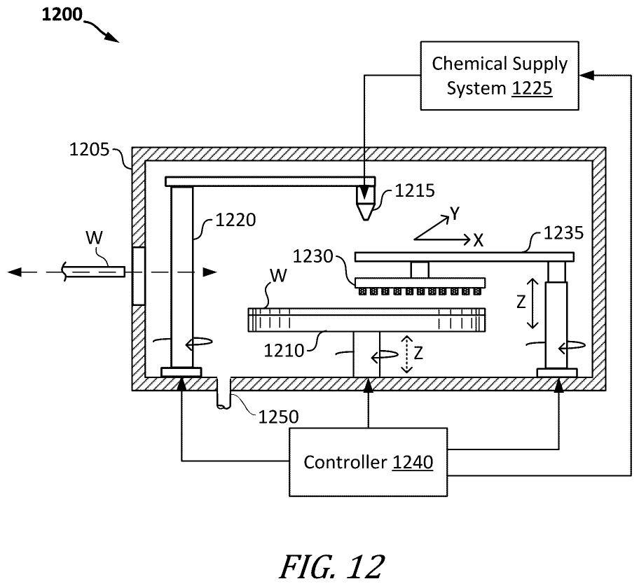

The MacEtch processes disclosed above may be performed within a wide variety of wet processing chambers. FIGS. 12-14 illustrate various examples of wet process processing systems in which the MacEtch processes disclosed herein can be performed. As described in more detail below, each of the wet processing systems shown in FIGS. 12-14 includes: (a) a substrate support mechanism (e.g., a spin chuck, support pins, wafer tray or carrier, etc.) configured to support a semiconductor substrate, (b) a chemical supply system coupled to supply an etch solution to at least one surface of the semiconductor substrate, (c) a processing head having one or more noble metal surfaces, (d) at least one mechanism coupled to the processing head and/or the substrate support mechanism to provide relative movement between the processing head and the semiconductor substrate supported by the substrate support mechanism, and (e) a controller coupled to the chemical supply system and the at least one mechanism.

The controller controls the MacEtch process by supplying control signals to the chemical supply system and the at least one mechanism. For example, the controller may supply: (a) a first set of control signals to the chemical supply system to expose the substrate surface to the etch solution, and (b) a second set of control signals to the at least one mechanism to position the processing head having the one or more noble metal surfaces in close proximity to the substrate surface, while the substrate surface is exposed to the etch solution, to perform a MacEtch process on the substrate surface and/or within the semiconductor substrate. In some embodiments, the controller may supply: (c) a third set of control signals to the at least one mechanism to continue to provide relative movement between the processing head and the semiconductor substrate during the MacEtch process, and (d) a fourth set of control signals to the at least one mechanism to remove the processing head from the substrate surface upon completion of the MacEtch process.

FIG. 12 illustrates one embodiment of a wet processing system 1200 that utilizes the techniques disclosed herein to process a semiconductor substrate. As shown in FIG. 12, the wet processing system 1200 includes a process chamber 1205 (e.g., a spin chamber) having a spin chuck 1210. A semiconductor substrate (e.g., a semiconductor wafer, W) is held on the spin chuck 1210, for example, via electrostatic force, vacuum pressure or mechanical support. The semiconductor substrate W may comprise a wide variety of semiconductor materials. In one embodiment, the semiconductor substrate W may be a silicon-containing substrate (e.g., Si, SiC or SiGe) or have a silicon-containing layer exposed on a surface of the substrate W. The spin chuck 1210 is configured to spin or rotate at a predetermined rotational speed. In some embodiments, the spin chuck 1210 may also be configured to move up/down in a direction (e.g., the z direction) perpendicular to the substrate surface.

The wet processing system 1200 further includes a liquid nozzle 1215, which can be positioned over the semiconductor substrate W for dispensing liquids (e.g., an etch solution, rinse solution, etc.) onto a surface of the substrate. In some embodiments, the liquid nozzle 1215 may dispense an etch solution comprising an oxidant and an etchant onto the substrate surface, as discussed above. The liquid nozzle 1215 is supported by a nozzle arm 1220, which can pivot toward and away from the semiconductor substrate W. For example, the nozzle arm 1220 may be located near a sidewall of the process chamber 1205 when loading a semiconductor substrate W onto the spin chuck 1210, and may be pivoted above the semiconductor substrate W when dispensing liquids onto the substrate surface.

The wet processing system 1200 further includes a chemical supply system 1225, which may include one or more reservoirs for holding various liquids (e.g., an etch solution, rinse solution, etc.) and a chemical injection manifold, which is fluidly coupled to the process chamber 1205 via a liquid supply line. In operation, the chemical supply system 1225 may selectively apply desired liquids to the process chamber 1205 via the liquid supply line and the liquid nozzle 1215 positioned above the semiconductor substrate W. Thus, the chemical supply system 1225 can be used to dispense an etch solution and other liquids onto the surface of the semiconductor substrate W. The process chamber 1205 may further include a drain 1250 for removing liquids from the process chamber 1205.

The wet processing system 1200 further includes a processing head 1230 having one or more metal surfaces (e.g., noble metal surfaces), which catalyze local reactions between the etch solution and portions of the substrate surface directly underlying the one or more metal surfaces when the processing head 1230 is positioned in close proximity to the substrate surface and the substrate surface is exposed to the etch solution. The processing head 1230 may comprise any of the processing head configurations shown in FIGS. 3-11 and described above. The processing head 1230 is support by a processing head arm 1235, which can pivot the processing head 1230 toward and away from the semiconductor substrate W and move the processing head 1230 up and down in a direction (e.g., the z direction) perpendicular to the substrate surface. In some embodiments, the processing head arm 1235 may also be configured to translate or scan the processing head 1230 across the substrate surface in an x- and/or y-direction.

Components of the wet processing system 1200 can be coupled to, and controlled by, a controller 1240, which in turn, can be coupled to a corresponding memory storage unit and user interface (not shown). Various processing operations can be executed via the user interface, and various processing recipes and operations can be stored in the memory storage unit. Accordingly, a given semiconductor substrate W can be processed within the process chamber 1205 in accordance with a particular recipe. In some embodiments, a semiconductor substrate W can be processed within the process chamber 1205 in accordance with a processing recipe that utilizes the MacEtch techniques described herein for etching one or more features within the semiconductor substrate or smoothing the substrate surface.

As shown in FIG. 12, the controller 1240 may be coupled to various components of the wet processing system 1200 to receive inputs from, and provide outputs to, the components. For example, the controller 1240 may be coupled to supply control signals to: the spin chuck 1210 for controlling the rotational speed (and/or the z-direction movement) of the spin chuck 1210; the chemical supply system 1225 for controlling the various liquids dispensed onto the substrate surface; the nozzle arm 1220 for controlling the location of the liquid nozzle 1215; and the processing head arm 1235 for controlling the location of the processing head 1230 and/or the x-, y- and/or z-direction movement of the processing head 1230. The controller 1240 may control other processing system components not shown in FIG. 12, as is known in the art.

In some embodiments, the controller 1240 may supply control signals to various components of the wet processing system 1200 to smooth the entire substrate surface. For example, the controller 1240 may supply control signals to the spin chuck 1210 to rotate the semiconductor substrate W at a predetermined rotational speed. Additional control signals may be supplied to the nozzle arm 1220 to position the liquid nozzle 1215 near the center of the semiconductor substrate W, the chemical supply system 1225 to dispense an etch solution onto the substrate surface, and the processing head arm 1235 to position the processing head 1230 in close proximity to the substrate surface to be smoothed. Depending on the particular configuration used, the processing head 1230 may be held stationary or scanned across the substrate surface (e.g., in an x- or y-direction) while substrate spins at the predetermined rotational speed. After the MacEtch smoothing process is complete, control signals are supplied to the processing head arm 1235 to raise the processing head 1230 and move it back to the home position. Additional control signals may be supplied to the chemical supply system 1225 to dispense a rinse solution (e.g., deionized water) onto the substrate surface, and the spin chuck 1210 to spin dry the substrate W.

In some embodiments, the controller 1240 may supply control signals to various components of the wet processing system 1200 to etch a pattern of features within the semiconductor substrate or perform local smoothing on the substrate surface. For example, the controller 1240 may supply control signals to the spin chuck 1210 to rotate the semiconductor substrate W at low rotational speed, the nozzle arm 1220 to position the liquid nozzle 1215 near the center of the semiconductor substrate W and the chemical supply system 1225 to dispense an etch solution onto the substrate surface. Once the substrate surface is coated with the etch solution, the substrate rotation and chemical dispense may gradually decrease to form a puddle of etch solution on the substrate surface. After puddle formation, the controller 1240 may supply control signals to the processing head arm 1235 to scan the processing head 1230 across the substrate surface (e.g., in an x- or y-direction), while the semiconductor substrate W remains stationary, to pattern or smooth specific locations on the substrate surface and/or within the semiconductor substrate. After the MacEtch patterning or local smoothing process is complete, control signals are supplied to the processing head arm 1235 to raise the processing head 1230 and move it back to the home position. Additional control signals may be supplied to the chemical supply system 1225 to dispense a rinse solution (e.g., deionized water) onto the substrate surface, and the spin chuck 1210 to spin dry the substrate W.

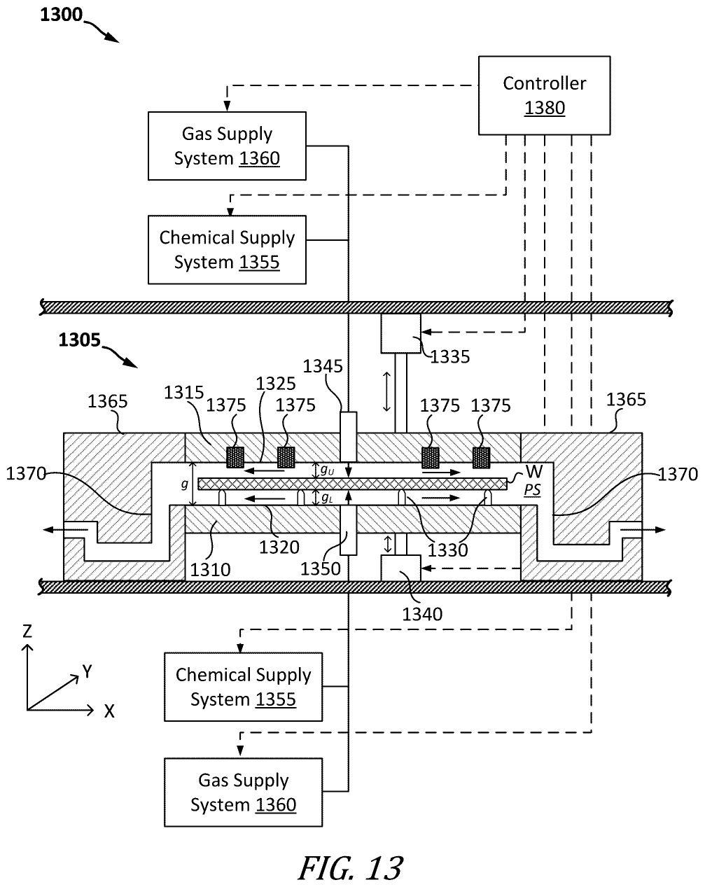

FIG. 13 illustrates another embodiment of a wet processing system 1300 that utilizes the techniques disclosed herein to process a semiconductor substrate. The wet processing system 1300 shown in FIG. 13 includes a process chamber 1305 in which a semiconductor substrate (e.g., a semiconductor wafer, W) is processed. The process chamber 1305 includes a bottom plate 1310 having portions defining a lower working surface 1320 inside the process chamber 1305, and a top plate 1315 having portions defining an upper working surface 1325 inside the process chamber 1305. The upper working surface 1325 inside the process chamber 1305 is spaced above the lower working surface 1320 and separated by a gap (g).

A processing space (PS) is formed between the upper working surface 1325 and the lower working surface 1320 of the process chamber 1305. The semiconductor substrate may be supported within the processing space (PS) by a variety of different substrate support mechanisms. For example, a plurality of pins 1330 may extend through the bottom plate 1310 into the processing space to support the substrate from the bottom, as shown in FIG. 13. Alternatively, edge supports may be provided within the processing space (PS) to support the edges of the substrate.

When a semiconductor substrate to be processed is inserted and mounted within the processing space (PS), an upper gap (g_{U}) is present between the upper working surface 1325 of the process chamber 1305 and the top surface of the substrate, and a lower gap (g_{L}) is present between the lower working surface 1320 of the process chamber 1305 and the bottom surface of the substate. The upper gap (g_{U}) and the lower gap (g_{L}) may be relatively small to limit the volume of the processing space (PS). In one example, the upper and lower gap may range between about 0.01 mm and about 10.0 mm.

The wet processing system 1300 further includes one or more lifting mechanisms 1335/1340 to adjust a vertical position of the top plate 1315 and/or a vertical position of the bottom plate 1310. In some embodiments, control signals may be supplied to the lifting mechanism 1335 to raise the top plate 1315, so that a semiconductor substrate can be inserted with the processing space (PS). Additional control signals may be supplied to the lifting mechanisms 1335/1340 to adjust the upper gap (g_{U}) between the upper working surface 1325 of the process chamber 1305 and the top surface of the semiconductor substrate and/or to adjust the lower gap (g_{L}) between the lower working surface 1320 of the process chamber 1305 and the bottom surface of the semiconductor substrate.

The wet processing system 1300 further includes one or more nozzles for dispensing processing fluids into the processing space (PS). In the embodiment shown in FIG. 13, the wet processing system 1300 includes at least one frontside nozzle 1345 extending through the top plate 1315 and at least one backside nozzle 1350 extending through the bottom plate 1310 for dispensing processing fluids into the processing space above and below the substrate. The nozzles 1345/1350 may dispense various processing fluids into the processing space, including liquids and gases. In the embodiment shown in FIG. 13, a chemical supply system 1355 may selectively apply desired liquids to the process chamber 1305 via the frontside nozzle 1345 positioned above the semiconductor substrate and/or the backside nozzle 1350 positioned below the semiconductor substrate. The chemical supply system 1355 may include one or more reservoirs for holding various liquids (e.g., an etch solution, rinse solution, etc.) and a chemical injection manifold, which is fluidly coupled to the process chamber 1305 via the nozzles 1345/1350 and one or more liquid supply lines. In some embodiments, the wet processing system 1300 may include a gas supply system 1360 for supplying various gases to the process chamber 1305 via the frontside nozzle 1345 and/or the backside nozzle 1350. The wet processing system 1300 may further include a drainage system 1365 containing a conduit 1370 for removing processing fluids (liquids and gases) from the processing space (PS). Additional components and features of the wet processing system 1300 are disclosed in U.S. patent application Ser. No. 18/192,279, entitled “Method and Single Wafer Processing System for Processing of Semiconductor Wafers,” filed on Mar. 29, 2023 and incorporated herein in its entirety.

The wet processing system 1300 further includes one or more processing heads 1375 having one or more metal surfaces (e.g., noble metal surfaces), which catalyze local reactions between an etch solution dispensed within the processing space (PS) and portions of the substrate surface directly underlying the one or more metal surfaces when the processing head(s) 1375 are positioned in close proximity to the substrate surface and the substrate surface is exposed to the etch solution. The processing head(s) 1375 may comprise any of the processing head configurations shown in FIGS. 3-11 and described above. In the embodiment shown in FIG. 13, the processing head(s) 1375 are supported by the top plate 1315, which as noted above, can be moved up and down in a direction (e.g., the z direction) perpendicular to the substrate surface by the lifting mechanism 1335. In some embodiments, the processing head(s) 1375 may also be translated or scanned across the substrate surface in an x- and/or y-direction.

Components of the wet processing system 1300 can be coupled to, and controlled by, a controller 1380, which in turn, can be coupled to a corresponding memory storage unit and user interface (not shown). Various processing operations can be executed via the user interface, and various processing recipes and operations can be stored in the memory storage unit. Accordingly, a given semiconductor substrate can be processed within the process chamber 1305 in accordance with a particular recipe. In some embodiments, a semiconductor substrate can be processed within the process chamber 1305 in accordance with a processing recipe that utilizes the MacEtch techniques described herein for etching one or more features within the semiconductor substrate or smoothing the substrate surface.

As shown in FIG. 13, the controller 1380 may be coupled to various components of the wet processing system 1300 to receive inputs from, and provide outputs to, the components. For example, the controller 1380 may be coupled to supply control signals to: the lifting mechanisms 1335/1340 for controlling the vertical position of the top plate 1315 and the bottom plate 1310; the chemical supply system 1355 for controlling the various liquids dispensed within the processing space (PS); and the gas supply system 1360 for controlling the various gases dispensed within the processing space (PS). The controller 1380 may control other processing system components not shown in FIG. 13, as is known in the art.

In some embodiments, the controller 1380 may supply control signals to various components of the wet processing system 1300 to etch a pattern of features within the semiconductor substrate or perform local smoothing on the substrate surface. For example, the controller 1380 may supply control signals to the chemical supply system 1355 to fill the processing space (PS) with an etch solution. Additional control signals may be supplied to the lifting mechanism 1335 and/or the lifting mechanism 1340 to position the processing head(s) 1375 in close proximity to the substrate surface to be etched or smoothed. The processing head(s) 1375 may contact the substrate surface at specific locations to pattern features within the semiconductor substrate or smooth specific locations on the substrate surface, or may be scanned across the substrate surface (e.g., in an x- or y-direction). After the MacEtch patterning or local smoothing process is complete, control signals are supplied to the lifting mechanism 1335 and/or the lifting mechanism 1340 to remove the processing head(s) 1375 from the substrate surface. Additional control signals may be supplied to the chemical supply system 1355 to dispense a rinse solution (e.g., deionized water) onto the substrate surface(s) to rinse the substrate surface(s), and the gas supply system 1360 to dispense dry air or nitrogen onto the substrate surface(s) to blow dry the substrate surface(s).

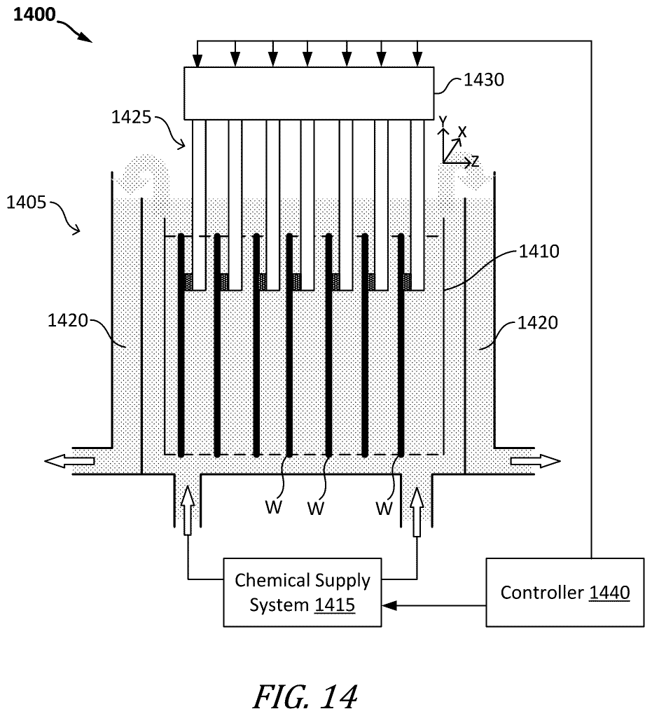

FIG. 14 illustrates another embodiment of a wet processing system 1400 that utilizes the techniques disclosed herein to process a semiconductor substrate. The wet processing system 1400 shown in FIG. 14 includes a processing tank 1405 in which a plurality of semiconductor substrates (e.g., 50) are concurrently processed. The semiconductor substrates W are supported by a wafer carrier 1410, which can be placed within and removed from the processing tank 1405. When disposed within the wafer carrier 1410, the semiconductor substrates W are clamped from the top and the bottom to hold the substrates securely in place.

The wet processing system 1400 further includes a chemical supply system 1415 for supplying various liquids (e.g., an etch solution, rinse solution, etc.) to the processing tank 1405, a drain 1420 for draining the liquids that overflow from the processing tank 1405 and a plurality of processing heads 1425 (e.g., 50) for performing MacEtch processes on the semiconductor substrates W disposed within the processing tank 1405. Each of the processing heads 1425 may have one or more metal surfaces (e.g., noble metal surfaces), which catalyze local reactions between an etch solution dispensed within the processing tank 1405 and portions of the substrate surface directly underlying the one or more metal surfaces when the processing head 1425 is positioned in close proximity to the substrate surface and the substrate surface is exposed to the etch solution. The processing heads 1425 may comprise any of the processing head configurations shown in FIGS. 3-11 and described above. In the embodiment shown in FIG. 14, a mechanism 1430 is coupled to the processing heads 1425 for moving the processing heads 1425 in an x-, y- and/or z-direction to position the processing heads 1425 and/or scan the processing heads 1425 across the substrate surfaces.

Components of the wet processing system 1400 can be coupled to, and controlled by, a controller 1440, which in turn, can be coupled to a corresponding memory storage unit and user interface (not shown). Various processing operations can be executed via the user interface, and various processing recipes and operations can be stored in the memory storage unit. Accordingly, the semiconductor substrates W can be processed within the processing tank 1405 in accordance with a particular recipe. In some embodiments, the semiconductor substrates W can be processed within the processing tank 1405 in accordance with a processing recipe that utilizes the MacEtch techniques described herein for etching one or more features within the semiconductor substrate or smoothing the substrate surface.

As shown in FIG. 14, the controller 1440 may be coupled to various components of the wet processing system 1400 to receive inputs from, and provide outputs to, the components. For example, the controller 1440 may be coupled to supply control signals to the mechanism 1430 for controlling the position of the processing heads 1425, and the chemical supply system 1415 for controlling the various liquids dispensed within the processing tank 1405. The controller 1440 may control other processing system components not shown in FIG. 14, as is known in the art.

In some embodiments, the controller 1440 may supply control signals to various components of the wet processing system 1400 to etch a pattern of features within the semiconductor substrate or perform local smoothing on the substrate surface. For example, the controller 1440 may supply control signals to the chemical supply system 1415 to fill the processing tank 1405 with an etch solution. Additional control signals may be supplied to the mechanism 1430 to position the processing heads 1425 in close proximity to the substrate surfaces to be etched or smoothed. The processing heads 1425 may contact the substrate surfaces at specific locations to pattern features within the semiconductor substrate or smooth specific locations on the substrate surface, or may be scanned across the substrate surface (e.g., in an x- or y-direction). After the MacEtch patterning or local smoothing process is complete, control signals are supplied to the mechanism 1430 to remove the processing heads 1425 from the substrate surfaces. Additional control signals may be supplied to the chemical supply system 1415 to dispense a rinse solution (e.g., deionized water) onto the substrate surfaces to rinse the substrate surfaces, and the mechanism 1430 to remove the processing heads 1425 from the processing tank 1405.

The controllers 1240/1380/1440 shown in block diagram form in FIGS. 12-14 can be implemented in a wide variety of manners. In one example, the controllers 1240/1380/1440 may each be a computer. In another example, the controllers may each include one or more programmable integrated circuits that are programmed to provide the functionality described herein. For example, one or more processors (e.g., microprocessor, microcontroller, central processing unit, etc.), programmable logic devices (e.g., complex programmable logic device (CPLD), field programmable gate array (FPGA), etc.), and/or other programmable integrated circuits can be programmed with software or other programming instructions to implement the functionality of a prescribed process recipe. It is further noted that the software or other programming instructions can be stored in one or more non-transitory computer-readable mediums (e.g., memory storage devices, flash memory, dynamic random access memory (DRAM), reprogrammable storage devices, hard drives, floppy disks, DVDs, CD-ROMs, etc.), and the software or other programming instructions when executed by the programmable integrated circuits can cause the programmable integrated circuits to perform the processes, functions, and/or capabilities described herein. Other variations could also be implemented.

Systems and methods for processing a semiconductor substrate are described in various embodiments. The term “semiconductor substrate” or “substrate” as used herein means and includes a base material or construction upon which materials are formed. It will be appreciated that the substrate may include a single material, a plurality of layers of different materials, a layer or layers having regions of different materials or different structures in them, etc. These materials may include semiconductors, insulators, conductors, or combinations thereof. For example, the substrate may be a semiconductor substrate, a base semiconductor layer on a supporting structure, a metal electrode or a semiconductor substrate having one or more layers, structures or regions formed thereon. The substrate may be a conventional silicon substrate or other bulk substrate comprising a layer of semi-conductive material. As used herein, the term “bulk substrate” means and includes not only silicon wafers, but also silicon-on-insulator (“SOI”) substrates, such as silicon-on-sapphire (“SOS”) substrates and silicon-on-glass (“SOG”) substrates, epitaxial layers of silicon on a base semiconductor foundation, and other semiconductor or optoelectronic materials, such as silicon-germanium, germanium, gallium arsenide, gallium nitride, and indium phosphide. The substrate may be doped or undoped.

The substrate may also include any material portion or structure of a device, particularly a semiconductor or other electronics device, and may, for example, be a base substrate structure, such as a semiconductor substrate or a layer on or overlying a base substrate structure. Thus, the term “substrate” is not intended to be limited to any particular base structure, underlying layer or overlying layer, patterned layer or unpatterned layer, but rather, is contemplated to include any such layer or base structure, and any combination of layers and/or base structures.

It is noted that reference throughout this specification to “one embodiment” or “an embodiment” means that a particular feature, structure, material, or characteristic described in connection with the embodiment is included in at least one embodiment of the invention, but do not denote that they are present in every embodiment. Thus, the appearances of the phrases “in one embodiment” or “in an embodiment” in various places throughout this specification are not necessarily referring to the same embodiment of the invention. Furthermore, the particular features, structures, materials, or characteristics may be combined in any suitable manner in one or more embodiments. Various additional layers and/or structures may be included and/or described features may be omitted in other embodiments.

One skilled in the relevant art will recognize that the various embodiments may be practiced without one or more of the specific details, or with other replacement and/or additional methods, materials, or components. In other instances, well-known structures, materials, or operations are not shown or described in detail to avoid obscuring aspects of various embodiments of the invention. Similarly, for purposes of explanation, specific numbers, materials, and configurations are set forth in order to provide a thorough understanding of the invention. Nevertheless, the invention may be practiced without specific details. Furthermore, it is understood that the various embodiments shown in the figures are illustrative representations and are not necessarily drawn to scale.

Further modifications and alternative embodiments of the methods described herein will be apparent to those skilled in the art in view of this description. It will be recognized, therefore, that the described methods are not limited by these example arrangements. It is to be understood that the forms of the methods herein shown and described are to be taken as example embodiments. Various changes may be made in the implementations. Thus, although the inventions are described herein with reference to specific embodiments, various modifications and changes can be made without departing from the scope of the present inventions. Accordingly, the specification and figures are to be regarded in an illustrative rather than a restrictive sense, and such modifications are intended to be included within the scope of the present inventions. Further, any benefits, advantages, or solutions to problems that are described herein with regard to specific embodiments are not intended to be construed as a critical, required, or essential feature or element of any or all the claims.

What is claimed is:

1. A method for processing a semiconductor substrate, the method comprising:
receiving the semiconductor substrate within a wet processing system, the wet processing system comprising a processing head having one or more metal surfaces at a distal end of the processing head;
exposing a substrate surface of the semiconductor substrate to an etch solution comprising an oxidant and an etchant while the semiconductor substrate is disposed within the wet processing system;
moving at least one of the processing head and the semiconductor substrate to position the one or more metal surfaces of the processing head in close proximity to the substrate surface while the substrate surface is exposed to the etch solution;
performing a metal assisted chemical etching (MacEtch) process on the substrate surface and/or within the semiconductor substrate while the one or more metal surfaces of the processing head is positioned in close proximity to the substrate surface and the substrate surface is exposed to the etch solution, wherein during the MacEtch process, the one or more metal surfaces of the processing head catalyze a reduction of the oxidant and generate free electron holes, which are injected into portions of the substrate surface directly underlying the one or more metal surfaces to form ionic species that are dissolved by the etchant; and
moving at least one of the processing head and the semiconductor substrate to remove the one or more metal surfaces of the processing head from the substrate surface upon completion of the MacEtch process.

2. The method of claim 1, wherein the one or more metal surfaces of the processing head comprise a noble metal.

3. The method of claim 1, wherein the oxidant comprises hydrogen peroxide (H₂O₂), nitric acid (HNO₃), potassium persulfate (K₂S₂O₈), oxygen (O₂) dissolved in water (H₂O) or ozonated water.

4. The method of claim 1, wherein the etchant comprises hydrofluoric acid (HF), sulfuric acid (H₂SO₄) or potassium hydroxide (KOH).

5. The method of claim 1, wherein said performing the MacEtch process comprises etching one or more features within the semiconductor substrate while the one or more metal surfaces of the processing head is positioned in close proximity to the substrate surface and the substrate surface is exposed to the etch solution.

6. The method of claim 5, wherein said performing the MacEtch process comprises etching one or more vertical holes or trenches within the semiconductor substrate.

7. The method of claim 5, wherein said performing the MacEtch process comprises etching one or more angled holes or trenches within the semiconductor substrate.

8. The method of claim 5, wherein said performing the MacEtch process comprises etching one or more horizontal holes or trenches within at least one vertical trench formed within the semiconductor substrate.

9. The method of claim 5, wherein said performing the MacEtch process comprises etching one or more circular disks within at least one vertical trench formed within the semiconductor substrate.

10. The method of claim 1, wherein said performing the MacEtch process comprises smoothing the substrate surface while the one or more metal surfaces of the processing head is positioned in close proximity to the substrate surface and the substrate surface is exposed to the etch solution.

11. A wet processing system, comprising:
a substrate support mechanism configured to support a semiconductor substrate, the semiconductor substrate having a substrate surface to be processed;
a chemical supply system coupled to supply an etch solution to the substrate surface, the etch solution comprising an oxidant and an etchant; and
a processing head having one or more noble metal surfaces, which catalyze local reactions between the etch solution and portions of the substrate surface directly underlying the one or more noble metal surfaces when the one or more noble metal surfaces of the processing head is positioned in close proximity to the substrate surface and the substrate surface is exposed to the etch solution.

12. The wet processing system of claim 11, further comprising:
at least one mechanism coupled to the processing head and/or the substrate support mechanism to provide relative movement between the processing head and the semiconductor substrate supported by the substrate support mechanism; and
a controller coupled to the chemical supply system and to the at least one mechanism, wherein the controller is configured to supply:
a first set of control signals to the chemical supply system to expose the substrate surface to the etch solution; and
a second set of control signals to the at least one mechanism to position the one or more noble metal surfaces of the processing head in close proximity to the substrate surface, while the substrate surface is exposed to the etch solution, to perform a metal assisted chemical etching (MacEtch) process on the substrate surface and/or within the semiconductor substrate;
wherein during the MacEtch process, the one or more noble metal surfaces of the processing head catalyze a reduction of the oxidant and generate free electron holes, which are injected into portions of the substrate surface directly underlying the one or more noble metal surfaces to form ionic species that are dissolved by the etchant.

13. The wet processing system of claim 12, wherein the controller is further configured to supply:
a third set of control signals to the at least one mechanism to continue the relative movement between the processing head and the semiconductor substrate during the MacEtch process; and
a fourth set of control signals to the at least one mechanism to remove the processing head from the substrate surface upon completion of the MacEtch process.

14. The wet processing system of claim 13, wherein the MacEtch process etches one or more features within the semiconductor substrate, and wherein the third set of control signals supplied to the at least one mechanism advances the processing head deeper within the one or more of features as the one or more features are being etched to increase a depth of the one or more features.

15. The wet processing system of claim 14, wherein the one or more features etched within the semiconductor substrate comprise one or more vertical holes or trenches.

16. The wet processing system of claim 14, wherein the one or more features etched within the semiconductor substrate comprise one or more angled holes or trenches.

17. The wet processing system of claim 13, wherein the MacEtch process etches one or more features within at least one vertical trench formed within the semiconductor substrate, and wherein the third set of control signals supplied to the at least one mechanism translates and/or rotates the processing head within the at least one vertical trench as the one or more features are being etched.

18. The wet processing system of claim 17, wherein the one or more features etched within the at least one vertical trench comprise one or more horizontal holes or trenches.

19. The wet processing system of claim 17, wherein the one or more features etched within the at least one vertical trench comprise one or more circular disks.

20. The wet processing system of claim 13, wherein the MacEtch process smooths the substrate surface, and wherein the third set of control signals supplied to the at least one mechanism advances the processing head toward the substrate surface and/or scans the processing head in a lateral direction across the substrate surface as the substrate surface is being smoothed.

21. The wet processing system of claim 11, wherein the processing head comprises an array of projections that extend from a lower surface of the processing head, and wherein distal ends of the array of projections are provided with the one or more noble metal surfaces, which catalyze the local reaction between the etch solution and the portions of the substrate surface directly underlying the one or more noble metal surfaces to etch a pattern of features within the semiconductor substrate.

22. The wet processing system of claim 21, wherein the processing head comprises a one-dimensional (1D) array of projections for etching a 1D pattern of features within the semiconductor substrate, or a two-dimensional (2D) array of projections for etching a 2D pattern of features within the semiconductor substrate.

23. The wet processing system of claim 21, wherein the array of projections extend at an angle ranging between 45° and 95° from a lower surface of the processing head.

24. The wet processing system of claim 21, wherein the array of projections comprise an array of cylindrical rods or an array of flat plates.

25. The wet processing system of claim 21, wherein the array of projections comprise an array of L-shaped rods or plates.
